(19) United States
(12) Patent Application Publication
(10) Pub. No.: US 2026/0161863 A1
(43) Pub. Date: Jun. 11, 2026

(54) SINGLE DIODE MODEL PARAMETER CALCULATION METHOD AND SYSTEM FOR PHOTOVOLTAIC MODULE

(71) Applicant: CHINA NATIONAL ELECTRIC APPARATUS RESEARCH INSTITUTE CO., LTD., Guangdong (CN)

(72) Inventors: Yonggao FU, Guangdong (CN); Yunhui LIU, Guangdong (CN); Nuo CAO, Guangdong (CN); Jiaqi HU, Guangdong (CN)

(73) Assignee: CHINA NATIONAL ELECTRIC APPARATUS RESEARCH INSTITUTE CO., LTD., Guangdong (CN)

(21) Appl. No.: 19/537,578

(22) Filed: Feb. 12, 2026

Related U.S. Application Data
(63) Continuation-in-part of application No. PCT/CN2024/124944, filed on Oct. 15, 2024.

(30) Foreign Application Priority Data
Jun. 14, 2024 (CN) 202410767792.9

(51) Int. Cl. G06F 30/31

(52) U.S. Cl. CPC G06F 30/31

(57) ABSTRACT

Disclosed is a single diode model parameter calculation method for a photovoltaic module. The method includes: firstly, on the basis of an equivalent circuit of a single diode model, obtaining a model under standard test conditions, and associating model parameters with test condition parameters to obtain a model for any test condition; and then acquiring performance parameters of the photovoltaic module, which include a short-circuit current, an open-circuit voltage, a maximum power-point current, a maximum power-point voltage, a temperature coefficient of the short-circuit current and a temperature coefficient of the open-circuit voltage, and constructing a system of equations and solving it to obtain model parameters. The present invention may realize the modeling and parameter identification of a model only on the basis of product specification information provided by a module manufacturer, without a complete I-V curve, thereby achieving a high guiding significance for simulation and production practices.

### CROSS-REFERENCE TO RELATED APPLICATION

This application is a continuation-in-part of international PCT application serial no. PCT/CN2024/124944, filed on Oct. 15, 2024, which claims the priority benefit of China application no. 202410767792.9, filed on Jun. 14, 2024. The entirety of each of the above mentioned patent applications is hereby incorporated by reference herein and made a part of this specification.

### BACKGROUND

### Technical Field

The present disclosure relates to the field of computation for photovoltaic module systems, and more particularly to a method and system for calculating parameters of a single diode model of a photovoltaic module.

### Description of Related Art

To address global climate warming and achieve the twin goals of carbon peak and carbon neutrality, photovoltaic power generation systems have been widely placed into operation. As a constituent component of such systems, the modeling of photovoltaic cells and the identification of their parameters are of substantial significance for the conduct of research concerning cell-structure optimization, forecasting of operating conditions, and related matters.

Models employed to assess the performance characteristics of photovoltaic modules include, without limitation, the single diode model, double diode model, and triple diode model. Among these, the single diode model has been widely adopted by virtue of its simplicity, high interpretability, and broad applicability. At present, notwithstanding some progress in parameter identification for the single diode model, such identification predominantly relies upon sampling points of the I-V curve; accordingly, completing parameter identification solely on the basis of information provided by manufacturers remains challenging.

### SUMMARY

It is an object of the present disclosure to provide a method and system for calculating the parameters of a single diode model for a photovoltaic module, which, utilizing only a minimal amount of product information, may determine the numerical values of respective parameters of the single diode model, and which are of significant guiding value for modeling and simulation as well as for manufacturing practice.

The above purpose of the present disclosure is achieved via the following technical solution: a single diode model parameter calculation method for photovoltaic modules is provided, wherein the calculation method includes the following steps:
Step 1: establishing a single diode model for any test condition;
Step 2: acquiring product information of a photovoltaic module;
Step 3: establishing and solving a system of equations to obtain a value of each of the parameters of the single diode model.

In the present disclosure, the step 1 specifically includes:
Step 1.1: obtaining the single diode model of a standard test condition (STC) based on an equivalent circuit of the photovoltaic module:

$$I = {I}_{ph , ref} - {I}_{o , r e f} [ exp ( \frac{V + {IR}_{s , ref}}{{n}_{r e f} {V}_{t , ref}} ) - 1 ] - \frac{V + {IR}_{s , ref}}{{R}_{sh , ref}} \qquad ( 1 )$$

Wherein I is a port current, V is a port voltage, R_{s,ref} is a standard value of a series resistance, R_{sh,ref} is a standard value of a parallel resistance, I_{ph,ref} is a standard value of a photogenerated current, I_{o,ref} is a standard value of a reverse saturation current, exp is an exponential power of e, n_{ref} is a standard value of an ideality factor, and V_{t,ref}=25.7 mV is a standard value of a thermal potential.
Step 1.2: introducing key test condition variables into the parameters of the single diode model, deriving an explicit expression of V with respect to I to obtain the single diode model for any test condition:

$$V = {R}_{s h} ( {I}_{p h} + {I}_{o} ) - ( {R}_{s h} + {R}_{s} ) I - {nV}_{t} W ( \frac{{I}_{o} {R}_{s h}}{n {V}_{t}} exp ( \frac{{R}_{s h} ( {I}_{ph} + {I}_{o} - I )}{n {V}_{t}} ) ) \qquad ( 2 )$$

Wherein W is a Lambert W function, Vₜ is a thermal potential of any test condition, Iₚₕ, Iₒ, n, Rₛ and Rₛₕ are a photogenerated current, a reverse saturation current, an ideality factor, a series resistance and a parallel resistance of the model in any test condition, respectively. When an irradiance of the test condition is G and a cell temperature is T, expressions of the parameters of the single diode model are:

$${I}_{p h} = \frac{G}{{G}_{r e f}} ( {I}_{ph , ref} + α ( T - {T}_{r e f} ) ) \qquad ( 3 )$$

$${I}_{o} = {{I}_{o , ref} ( \frac{T}{{T}_{ref}} )}^{3} exp ( \frac{{E}_{g , ref}}{k} ( \frac{1}{{T}_{ref}} - \frac{1 + γ ( T - {T}_{ref} )}{T} ) ) \qquad ( 4 )$$

$$n = {n}_{ref} \qquad ( 5 )$$

$${R}_{s} = {R}_{s , ref} \frac{T}{{T}_{ref}} \qquad ( 6 )$$

$${R}_{s h} = {R}_{sh , ref} \frac{{G}_{ref}}{G} \qquad ( 7 )$$

Wherein G_{ref}=1000 W/m² is the irradiance of the STC, T_{ref}=298.15K is the cell temperature of the STC, E_{g,ref} is a standard value of a band gap of a photovoltaic cell p-n junction, k=1.38×10⁻²³ J/K is a Boltzmann constant, α represents a temperature coefficient of a short-circuit current, and γ represents a temperature coefficient of a material band gap.

In the present disclosure, in the step 2, the product information of the photovoltaic module includes the short-circuit current I_{sc,ref}, an open-circuit voltage V_{oc,ref}, a maximum power-point current I_{m,ref}, a maximum power-point voltage V_{m,ref}, the temperature coefficient α of the short-circuit current and a temperature coefficient β of the open-circuit voltage, these parameters may be obtained by consulting a product manual or inquiring the manufacturer or an active test.

In the present disclosure, the step 3 specifically includes:
Step 3.1: establishing the system of equations consisting of five equations:

$$\{ \begin{matrix}f ( {I}_{sc , ref} ) = 0 \\ f ( 0 ) - {V}_{oc , ref} = 0 \\ f ( {I}_{m , r e f} ) - {V}_{m , ref} = 0 \\ f ( {I}_{m , r e f} ) + {f}^{′} ( {I}_{m , ref} ) {I}_{m , r e f} = 0 \\ {g}^{′} ( {T}_{ref} + Δ T ) - β = 0\end{matrix} \qquad ( 8 )$$

Wherein ƒ represents a functional relationship between the port voltage and the port current, ƒ′ represents a derivative of a function ƒ with respect to the port current, g represents a functional relationship between the open-circuit voltage and the cell temperature, g′ represents a derivative of the function g, T_{ref}=298.15K is the cell temperature of the STC, ΔT is a cell temperature change, β represents the temperature coefficient of the open-circuit voltage, expressions of ƒ(I), ƒ′(I) and g′(T) are respectively as follows:

$$f ( I ) = {R}_{sh , ref} ( {I}_{ph , ref} + {I}_{o , r e f} ) - ( {R}_{sh , ref} + {R}_{s , ref} ) I - {n}_{r e f} {V}_{t , ref} W ( {X}_{r e f} ) \qquad ( 9 )$$

$${f}^{′} ( I ) = - {R}_{s , ref} - \frac{{R}_{sh , ref}}{1 + W ( {X}_{r e f} )} \qquad ( 10 )$$

$${g}^{′} ( T ) = {R}_{sh , ref} ( α + A ( T ) ) - C ( T ) {n}_{r e f} {V}_{t , ref} ( \frac{1}{{T}_{r e f}} + \frac{D ( T )}{1 + C ( T )} ) \qquad ( 11 )$$

Wherein I is the port current, T is the cell temperature, X_{ref}, A(T), C(T) and D(T) are all intermediate variables, the expressions are as follows:

$${X}_{ref} = \frac{{I}_{o , ref} {R}_{sh , ref}}{{n}_{ref} {V}_{t , ref}} exp ( \frac{{R}_{sh , ref} ( {I}_{{ph , ref}^{}} + {I}_{o , ref} - I )}{{n}_{r e f} {V}_{t , ref}} ) \qquad ( 12 )$$

$$A ( T ) = {I}_{o , ref} exp ( \frac{{E}_{g , ref}}{k} ( \frac{1}{{T}_{ref}} - \frac{1 + γ ( T - {T}_{ref} )}{T} ) ) \frac{{T}^{2}}{{T}_{ref}^{3}} ( 3 + \frac{{E}_{g , ref} ( 1 - γ {T}_{ref} )}{kT} ) \qquad ( 13 )$$

$$C ( T ) = \frac{{{T}_{ref} ( {R}_{sh , ref} ( {I}_{ph} ( T ) + {I}_{o} ( T ) ) - ( {V}_{oc , ref} + β ( T - {T}_{ref} ) ) )}_{}}{{n}_{ref} {V}_{t , ref} T} \qquad ( 14 )$$

$$D ( T ) = \frac{{R}_{sh , ref}}{{n}_{ref} {V}_{t , ref}} ( α + A ( T ) - \frac{{I}_{ph} ( T ) + {I}_{o} ( T )}{T} ) + \frac{A ( T )}{{I}_{o , ref} + A ( T )} - \frac{1}{T} \qquad ( 15 )$$

Step 3.2: solving the system of equations to get parameter values of the single diode model by using a trust region dogleg method.

The present disclosure may be improved as follows: the method further includes step 4: simulating performance indicators of the photovoltaic module via the expression of the single diode model obtained in step 1.2 and the parameters of the single diode model obtained in step 3.2, and calculating relative errors between the simulated performance indicators and actual performance indicators of the photovoltaic module, thereby evaluating whether the calculation method may be used for actual simulation.

A single diode model parameter calculation system for the photovoltaic module is provided, and the system includes:
A data reading module, configured to acquire product information of the photovoltaic module;
A parameter calculation module, configured to calculate values of parameters of the single diode model;
A simulation calculation module, configured to simulate performance indicators and relative errors of the photovoltaic module.

Compared with the related art, the present disclosure has the following advantageous effects:
First, a single diode model for any test condition is established, which may be used for calculating the performance of the module under different irradiance and different temperature conditions;
Second, six key indicators including the short-circuit current, the open-circuit voltage, the maximum power-point current, the maximum power-point voltage, the temperature coefficient of the short-circuit current and the temperature coefficient of the open-circuit voltage are extracted from the product information for parameter identification;
Third, the parameter identification method is simple, the model parameters may be directly obtained only by solving the established system of equations;
Fourth, the present disclosure may complete the parameter identification of the model only by relying on the product information, without requiring a complete I-V curve, avoiding the inconvenience of additional data collection.

### BRIEF DESCRIPTION OF THE DRAWINGS

The present disclosure is further described in detail below in conjunction with the accompanying drawings and specific embodiments.

FIG. 1 is a schematic diagram of an equivalent circuit of a single diode model under standard test conditions provided in an embodiment of the present disclosure.

FIG. 2 is a flow diagram of a single diode model parameter calculation method for a photovoltaic module of the present disclosure.

### DESCRIPTION OF THE EMBODIMENTS

### Embodiment 1

As shown in FIG. 2, a single diode model parameter calculation method for a photovoltaic module includes the following steps:
Step 1: establishing a single diode model for any test condition;
Step 2: acquiring product information of the photovoltaic module;
Step 3: establishing and solving a system of equations to obtain model parameters;
Step 4: simulating and calculating relative errors of performance indicators.

The specific process of each step is as follows:

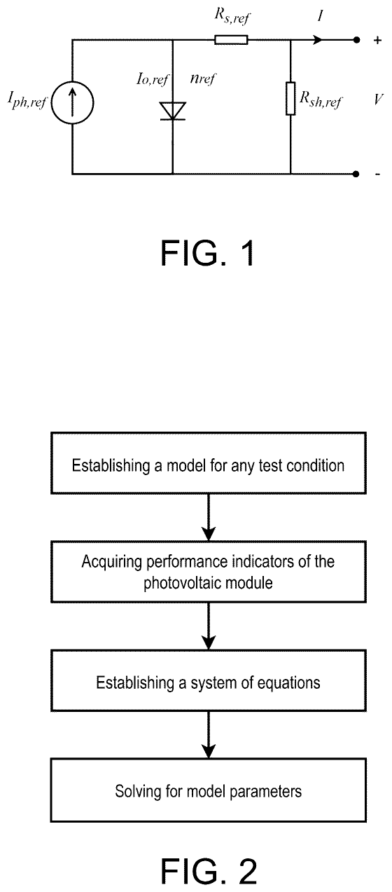

In step 1, the steps of establishing the single diode model include:
Step 1.1: establishing the single diode model under standard test conditions: an equivalent circuit of the single diode is shown in FIG. 1.

In FIG. 1, a current-voltage function relationship corresponding to the equivalent circuit is:

$$I = {I}_{ph , ref} - {I}_{o , ref} [ exp ( \frac{V + I {R}_{s , ref}}{{n}_{ref} {V}_{t , ref}} ) - 1 ] - \frac{V + I {R}_{s , ref}}{{R}_{sh , ref}} \qquad ( 1 )$$

Wherein I is a port current, V is a port voltage, R_{s,ref} is a standard value of a series resistance, R_{sh,ref} is a standard value of a parallel resistance, I_{ph,ref} is a standard value of a photogenerated current, I_{o,ref} is a standard value of a reverse saturation current, exp is an exponential power of e, n_{ref} is a standard value of an ideality factor, V_{t,ref}=25.7 mV is a standard value of a thermal potential. The model under standard test conditions has a narrow applicable range and may not cope with various actual test conditions, so it is necessary to further establish a model for general test conditions.
Step 1.2: establishing a single diode model under any test conditions:
Irradiance and temperature in the test condition may affect the values of the model parameters, thereby changing the performance of the module, so the model under standard test conditions (STC) is extended to any test conditions to obtain:

$$I = {I}_{p h} - {I}_{o} [ exp ( \frac{V + I {R}_{s}}{n {V}_{t}} ) - 1 ] - \frac{V + I {R}_{s}}{{R}_{s h}} \qquad ( 2 )$$

Wherein V and I are a port voltage and a port current respectively, Vₜ is a thermal potential of the test condition, Iₚₕ, Iₒ, n, Rₛ and Rₛₕ are a photogenerated current, a reverse saturation current, an ideality factor, a series resistance and a parallel resistance of the model in the test condition respectively. The foregoing expression is not well suited to an intuitive presentation of the relationship between voltage and current and may be further converted as follows:

$$V = {R}_{s h} ( {I}_{p h} + {I}_{o} ) - ( {R}_{s h} + {R}_{s} ) I - {nV}_{t} W ( X ) \qquad ( 3 )$$

Wherein W is a Lambert W function,

$$X = \frac{{I}_{o} {R}_{s h}}{n {V}_{t}} exp ( \frac{{R}_{s h} ( {I}_{p h} + {I}_{o} - I )}{n {V}_{t}} )$$

is an intermediate variable.

The STC is a special case of any test conditions, and there is a specific relationship between the model parameters of the two conditions. Establishing an association between Iₚₕ, Iₒ, n, Rₛ, Rₛₕ and Iₚₕ, ref, I_{o,ref}, n_{ref}, R_{s,ref}, R_{sh,ref} to obtain:

$${I}_{p h} = \frac{G}{{G}_{ref}} ( {I}_{ph , ref} + α ( T - {T}_{ref} ) ) \qquad ( 4 )$$

$${I}_{o} = {{I}_{o , ref} ( \frac{T}{{T}_{ref}} )}^{3} exp ( \frac{{E}_{g , ref}}{k} ( \frac{1}{{T}_{ref}} - \frac{1 + γ ( T - {T}_{ref} )}{T} ) ) \qquad ( 5 )$$

$$n = {n}_{ref} \qquad ( 6 )$$

$${R}_{s} = {R}_{s , ref} \frac{T}{{T}_{ref}} \qquad ( 7 )$$

$${R}_{s h} = {R}_{sh , ref} \frac{{G}_{ref}}{G} \qquad ( 8 )$$

Wherein G_{ref}=1000 W/m² is the irradiance of the STC, T_{ref}=298.15K is a cell temperature of the STC, E_{g,ref} is a standard value of a band gap of a photovoltaic cell p-n junction, which is 1.12 eV for monocrystalline silicon cells, k=1.38×10⁻²³ J/K is a Boltzmann constant. G represents the irradiance of the test condition, T represents the cell temperature of the test condition, α represents a temperature coefficient of a short-circuit current, γ represents a temperature coefficient of a material band gap, which is −0.02677%/K for the monocrystalline silicon cells.

In step 2, the step of acquiring the product information of the photovoltaic module includes:
A product manual is consulted obtain the performance indicators of the photovoltaic module under the STC, including the short-circuit current I_{sc,ref}, an open-circuit voltage V_{oc,ref}, a maximum power-point current I_{m,ref}, a maximum power-point voltage V_{m,ref}, the temperature coefficient α of the short-circuit current and a temperature coefficient β of the open-circuit voltage. When α and β are expressed in percentages, their values are converted to αI_{sc,ref} and βV_{oc,ref} respectively. All performance indicators are shown in the given values in Table 2.

In step 3, the step of obtaining the model parameters includes:
Step 3.1: establishing the system of equations.

SDM has five parameters, and the parameter values may be obtained by constructing five equations and solving the corresponding system of equations. The relationship between voltages and currents in the standard test condition is as follows:

$$V = f ( I ) = {R}_{sh , ref} ( {I}_{ph , ref} + {I}_{o , r e f} ) - ( {R}_{sh , ref} + {R}_{s , ref} ) I - {n}_{r e f} {V}_{t , ref} W ( {X}_{r e f} ) \qquad ( 9 )$$

Wherein ƒ is a function symbol,

$${X}_{ref} = \frac{{I}_{o , ref} {R}_{sh , ref}}{{n}_{ref} {V}_{t , ref}} exp ( \frac{{R}_{sh , ref} ( {I}_{{ph , ref}^{}} + 1 = {I}_{o , ref} - I )}{{n}_{r e f} {V}_{t , ref}} )$$

is the intermediate variable.

A point coordinates (I_{sc,ref}, 0) of the short-circuit is utilized to obtain a first equation:

$$f ( {I}_{sc , ref} ) = 0 \qquad ( 10 )$$

Similarly, an open-circuit point and the maximum power-point are utilized to obtain the second and third equations respectively:

$$f ( 0 ) = {V}_{oc , ref} \qquad ( 11 )$$

$$f ( {I}_{m , ref} ) = {V}_{m , ref} \qquad ( 12 )$$

For the maximum power-point, the condition that power is an extreme point is also satisfied, thus the fourth equation may be obtained:

$${P}^{′} ( {I}_{m , ref} ) = f ( {I}_{m , ref} ) + {f}^{′} ( {I}_{m , r e f} ) {I}_{m , ref} = 0 \qquad ( 13 )$$

Wherein P′ represents a derivative of a power P with respect to the port current, ƒ′ represents a derivative of a function ƒ, and an expression of ƒ′(I) is:

$${f}^{′} ( I ) = - {R}_{s , ref} - \frac{{R}_{sh , ref}}{1 + W ( {X}_{ref} )} \qquad ( 14 )$$

In the test condition, the irradiance is fixed at 1000 W/m², and the cell temperature T is regarded as a variable, in which case an expression of the open-circuit voltage is:

$${V}_{oc} = g ( T ) = {R}_{sh , ref} ( {I}_{ph} ( T ) + {I}_{o} ( T ) ) - {n}_{ref} {V}_{t} ( T ) W ( X ( T ) ) \qquad ( 15 )$$

Wherein g is a function symbol,

$$X ( T ) = \frac{{R}_{sh , ref} {I}_{o} ( T )}{{n}_{ref} {V}_{t} ( T )} exp ( \frac{{R}_{sh , ref} ( {I}_{ph} ( T ) + {I}_{o} ( T ) )}{{n}_{ref} {V}_{t} ( T )} )$$

is the intermediate variable. The expressions of Vₜ(T), Iₚₕ(T) and Iₒ(T) are respectively as follows:

$${V}_{t} ( T ) = \frac{{V}_{t , ref}}{{T}_{ref}} T \qquad ( 16 )$$

$${I}_{ph} ( T ) = {I}_{ph , ref} + α ( T - {T}_{ref} ) \qquad ( 17 )$$

$${I}_{o} ( T ) = {I}_{o , ref} + A ( T ) ( T - {T}_{ref} ) \qquad ( 18 )$$

Wherein A(T) represents a temperature coefficient of a reverse saturation current at the temperature T, and its expression is as follows:

$$A ( T ) = {I}_{o , ref} exp ( \frac{{E}_{g , ref}}{k} ( \frac{1}{{T}_{ref}} - \frac{1 + γ ( T - {T}_{ref} )}{T} ) ) \frac{{T}^{2}}{{T}_{ref}^{3}} ( 3 + \frac{{E}_{g , ref} ( 1 - γ {T}_{ref} )}{k T} ) \qquad ( 19 )$$

Then the temperature coefficient β of the open-circuit voltage is obtained:

$${g}^{′} ( T ) = {R}_{sh , ref} ( α + A ( T ) ) - C ( T ) {n}_{ref} {V}_{t , ref} ( \frac{1}{{T}_{ref}} + \frac{D ( T )}{1 + C ( T )} ) \qquad ( 20 )$$

Wherein g′(T) represents a derivative of a function g, C(T) and D(T) are both intermediate variables, and the expressions are as follows:

$$C ( T ) = \frac{{T}_{ref} ( {R}_{sh , ref} ( {I}_{ph} ( T ) + {I}_{o} ( T ) ) - ( {V}_{oc , ref} + β ( T - {T}_{ref} ) ) )}{{n}_{ref} {V}_{t , ref} T} \qquad ( 21 )$$

$$D ( T ) = \frac{{R}_{sh , ref}}{{n}_{ref} {V}_{t , ref}} ( α + A ( T ) - \frac{{I}_{ph} ( T ) + {I}_{o} ( T )}{T} ) + \frac{A ( T )}{{I}_{o , ref} + A ( T )} - \frac{1}{T} \qquad ( 22 )$$

Thus the fifth equation is obtained:

$${g}^{′} = ( {T}_{ref} + Δ T ) = β \qquad ( 23 )$$

Wherein T_{ref}=298.15K is the temperature of the STC, ΔT represents a temperature change, preferably taken as 1K.

Combining the above five equations, the system of equations is obtained:

$$\{ \begin{matrix}f ( {I}_{sc , ref} ) = 0 \\ f ( 0 ) - {V}_{oc , ref} = 0 \\ f ( {I}_{m , ref} ) - {V}_{m , ref} = 0 \\ f ( {I}_{m , ref} ) + {f}^{′} ( {I}_{m , ref} ) {I}_{m , ref} = 0 \\ {g}^{′} ( {T}_{ref} + Δ T ) - β = 0\end{matrix} \qquad ( 24 )$$

Step 3.2: solving an equation (24) by using a trust region dogleg method to obtain the numerical value of each of the model parameters.

In step 4, the steps for calculating relative errors of performance indicators via simulation include:
Step 4.1: simulating performance indicators of the photovoltaic module via the expression of the single diode model obtained in step 1.2 and the model parameters obtained in step 3.2, the specific process is as follows:
S1, substituting the model parameters into an equation (9), solving ƒ (I_{sc})=0 by using the trust region dogleg method to obtain a simulation value I_{sc} of the short-circuit current;
S2, substituting the model parameters into the equation (9), calculating ƒ (0) to obtain a simulation value V_{oc} of the open-circuit voltage;
S3, for the irradiance G=1000 W/m² and the cell temperature T=299.15K of a non-standard test condition, deriving parameters of the non-standard test condition by using the model parameters and equations (4-8);
S4, changing the model parameters to the parameters of the non-standard test condition, deriving the simulation value I_{sc} of the short-circuit current of the non-standard test condition by using S1, deriving the simulation value \tilde{V}_{oc} of the open-circuit voltage of the non-standard test condition by using S2, then the temperature coefficient of the short-circuit current is α=Ĩ_{sc}−I_{sc}, and the temperature coefficient of the open-circuit voltage is β=\tilde{V}_{oc}−V_{oc}.
Step 4.2: calculating relative errors between simulation performance indicators and actual performance indicators of the photovoltaic module, if the relative errors between the two are within the range of +6%, it indicates that this calculation method may be used for actual simulation.

In this embodiment, based on the relevant data obtained from the product manual of the monocrystalline silicon photovoltaic module, parameters estimation are performed via equations, and the obtained model parameters of the photovoltaic module under the STC are shown in Table 1.

TABLE 1
Estimated values of model parameters for monocrystalline silicon module

| | | | | Series | |
|---|---|---|---|---|---|
| | Photogenerated | Reverse saturation | Ideality | resistance | Parallel |
| Model parameters | current (A) | current (A) | factor | (Ω) | resistance (Ω) |
| Patented method | 18.612 | 6.968 × 10⁻¹² | 66.160 | 5.700 × 10⁻³ | 64.880 |
| Reference method | 18.325 | 4.974 × 10⁻⁹ | 85.800 | 2.260 × 10⁻² | 85.460 |

The reference method is derived from the method disclosed in the patent document with patent number CN202311237791.5, titled “Photovoltaic Module Parameter Estimation Method and System Based on Newton-Raphson Method”.

The simulation values of module performance indicators calculated by using the model expression and the model parameters, as well as the comparison results between the given values and simulation values are shown in Table 2.

TABLE 2
Given values and simulation results of performance indicators of monocrystalline silicon module

| | | | Maximum | Maximum | Temperature | Temperature |
|---|---|---|---|---|---|---|
| | Short-circuit | Open-circuit | power-point | power-point | coefficient of | coefficient of |
| Performance | current Isc | voltage Voc | current Im | voltage Vm | short-circuit | open-circuit |
| indicators | (A) | (V) | (A) | (V) | current (A/K) | voltage (V/K) |
| Given value | 18.32 | 48.60 | 17.29 | 40.50 | 7.328 × 10⁻³ | −0.1166 |
| Simulation | 18.61 | 48.61 | 17.29 | 42.90 | 7.439 × 10⁻³ | −0.1216 |
| value | | | | | | |
| Relative error | 1.587% | 0.023% | −0.007% | 4.947% | 1.513% | 4.235% |
| Simulation | 18.32 | 48.53 | 16.95 | 41.53 | 7.312 × 10⁻³ | −0.2063 |
| value (1) | | | | | | |
| Relative error | −1.572 × 10⁻⁸ | −0.142% | −1.959% | 2.114% | −0.221% | 76.85% |
| (1) | | | | | | |

The simulation values and relative errors marked with (1) are the simulation results derived by using the reference method.

As evidenced by Table 2, absolute values of the relative errors for the short-circuit current, the maximum power-point voltage, and the temperature coefficient of the short-circuit current in the present disclosure are larger, and the corresponding simulation results are marginally inferior to those of the reference method. However, the simulation results for the remaining three indicators are superior, wherein the relative error of the temperature coefficient of the open-circuit voltage is substantially lower than that of the reference method. Upon comprehensive comparison, the performance indicators obtained from the simulation of the present disclosure all fall within an engineering-permissible tolerance of ±6%, and may accordingly be employed for practical modeling and simulation.

### Embodiment 2

The present embodiment provides a photovoltaic module single diode model parameter calculation system, and the system includes:
A data reading module, configured to acquire product information of the photovoltaic module;
A parameter calculation module, configured to calculate parameter values of the single diode model;
A simulation calculation module, configured to simulate performance indicators and relative errors of the photovoltaic module.

### Embodiment 3

The present embodiment provides an electronic device capable of calculating single diode model parameters of a photovoltaic module. In a specific implementation, the electronic device may be in the form of a user terminal, for example, the electronic device may be, but is not limited to, a server, a smartphone, a personal computer, or an embedded system, etc.

The electronic device has a single diode model parameter calculation component, such as a central processing unit, or a graphics processing unit, etc., and has a memory for storing a computer program. When the electronic device is operating, the processor executes the computer program stored in the memory, so that the electronic device executes the model parameter calculation method provided by the present embodiment.

The electronic device may also have a storage component for storing photovoltaic module performance data, for example, a mechanical hard disk, a mobile hard disk, a memory card, etc., so that it may also save the performance data provided by the present embodiment, as well as the parameter values obtained by executing the single diode model parameter calculation method of the photovoltaic module provided by the present embodiment via the computer program, and use them for output display.

What is claimed is:

1. A single diode model parameter calculation method for a photovoltaic module, the calculation method comprising following steps:
a step 1: establishing a single diode model for any test condition;
a step 2: acquiring product information of a photovoltaic module;
a step 3: establishing and solving a system of equations to obtain a value of each of parameters of the single diode model.

2. The single diode model parameter calculation method for the photovoltaic module according to claim 1, wherein the step 1 comprises:
a step 1.1: obtaining the single diode model of a standard test condition (STC) based on an equivalent circuit of the photovoltaic module:
$$I = {I}_{ph , ref} - {I}_{o , ref} [ exp ( \frac{V + {IR}_{s , ref}}{{n}_{ref} {V}_{t , ref}} ) - 1 ] - \frac{V + {IR}_{s , ref}}{{R}_{sh , ref}} \qquad ( 1 )$$
wherein I is a port current, V is a port voltage, R_{s,ref} is a standard value of a series resistance, R_{sh,ref} is a standard value of a parallel resistance, I_{ph,ref} is a standard value of a photogenerated current, I_{o,ref} is a standard value of a reverse saturation current, exp is an exponential power of e, n_{ref} is a standard value of an ideality factor, and V_{t,ref}=25.7 mV is a standard value of a thermal potential;
a step 1.2: introducing key test condition variables into the parameters of the single diode model, deriving an explicit expression of V with respect to/to obtain the single diode model for the any test condition;
$$V = {R}_{sh} ( {I}_{ph} + {I}_{o} ) - ( {R}_{sh} + {R}_{s} ) I - {nV}_{t} W ( \frac{{I}_{o} {R}_{sh}}{{nV}_{t}} exp ( \frac{{R}_{sh} ( {I}_{ph} + {I}_{o} - 1 )}{{nV}_{t}} ) ) \qquad ( 2 )$$
wherein W is a Lambert W function, Vₜ is a thermal potential of the any test condition, Iₚₕ, Iₒ, n, Rₛ and Rₛₕ are a photogenerated current, a reverse saturation current, an ideality factor, a series resistance and a parallel resistance of the model in the any test condition, respectively, when an irradiance of the test condition is G and a cell temperature is T, expressions of the parameters of the single diode model are:
$${I}_{ph} = \frac{G}{{G}_{ref}} ( {I}_{ph , ref} + α ( T - {T}_{ref} ) ) \qquad ( 3 )$$
$${I}_{o} = {{I}_{o , ref} ( \frac{T}{{T}_{ref}} )}^{3} exp ( \frac{{E}_{g , ref}}{k} ( \frac{1}{{T}_{ref}} - \frac{1 + γ ( T - {T}_{ref} )}{T} ) ) \qquad ( 4 )$$
$$n = {n}_{ref} \qquad ( 5 )$$
$${R}_{s} = {R}_{s , ref} \frac{T}{{T}_{ref}} \qquad ( 6 )$$
$${R}_{sh} = {R}_{sh , ref} \frac{{G}_{ref}}{G} \qquad ( 7 )$$
wherein G_{ref}=1000 W/m² is an irradiance of the STC, T_{ref}=298.15K is a cell temperature of the STC, E_{g,ref} is a standard value of a band gap of a photovoltaic cell p-n junction, k=1.38×10⁻²³ J/K is a Boltzmann constant, α represents a temperature coefficient of a short-circuit current, and γ represents a temperature coefficient of a material band gap.

3. The single diode model parameter calculation method for the photovoltaic module according to claim 2, wherein in the step 2, the product information of the photovoltaic module comprises the short-circuit current I_{sc,ref}, an open-circuit voltage V_{oc,ref}, a maximum power-point current I_{m,ref}, a maximum power-point voltage V_{m,ref}, the temperature coefficient α of the short-circuit current and a temperature coefficient β of the open-circuit voltage.

4. The single diode model parameter calculation method for the photovoltaic module according to claim 3, wherein the step 3 comprises:
a step 3.1: establishing the system of equations consisting of five equations:
$$\{ \begin{matrix}f ( {I}_{sc , ref} ) = 0 \\ f ( 0 ) - {V}_{oc , ref} = 0 \\ f ( {I}_{m , ref} ) - {V}_{m , ref} = 0 \\ f ( {I}_{m , ref} ) + {f}^{′} ( {I}_{m , ref} ) {I}_{m , ref} = 0 \\ {g}^{′} ( {T}_{ref} + Δ T ) - β = 0\end{matrix} \qquad ( 8 )$$
wherein ƒ represents a functional relationship between the port voltage and the port current, ƒ′ represents a derivative of a function ƒ, g represents a functional relationship between the open-circuit voltage and the cell temperature, g′ represents a derivative of a function g, T_{ref}=298.15K is the cell temperature of the STC, ΔT=1K is a cell temperature change, β represents the temperature coefficient of the open-circuit voltage, expressions of ƒ(I), ƒ′(I) and g′(T) are respectively as follows:
$$f ( I ) = {R}_{sh , ref} ( {I}_{ph , ref} + {I}_{o , ref} ) - ( {R}_{sh , ref} + {R}_{s , ref} ) I - {n}_{ref} {V}_{t , ref} W ( {X}_{ref} ) \qquad ( 9 )$$
$${f}^{′} ( I ) = {R}_{s , ref} - \frac{{R}_{sh , ref}}{1 + W ( {X}_{ref} )} \qquad ( 10 )$$
$${g}^{′} ( T ) = {R}_{sh , ref} ( α + A ( T ) ) - C ( T ) {n}_{ref} {V}_{t , ref} ( \frac{1}{{T}_{ref}} + \frac{D ( T )}{1 + C ( T )} ) \qquad ( 11 )$$
wherein I is the port current, T is the cell temperature, X_{ref}, A(T), C(T) and D(T) are all intermediate variables, expressions thereof are as follows:
$${X}_{ref} = \frac{{I}_{o , ref} {R}_{sh , ref}}{{n}_{ref} {V}_{t , ref}} exp ( \frac{{R}_{sh , ref} ( {I}_{ph , ref} + {I}_{o , ref} - I )}{{n}_{ref} {V}_{t , ref}} ) \qquad ( 12 )$$
$$A ( T ) = {I}_{o , ref} exp ( \frac{{E}_{g , ref}}{k} ( \frac{1}{{T}_{ref}} - \frac{1 + γ ( T - {T}_{ref} )}{T} ) ) \frac{{T}^{2}}{{T}_{ref}^{3}} ( 3 + \frac{{E}_{g , ref} ( 1 - γ {T}_{ref} )}{k T} ) \qquad ( 13 )$$
$$C ( T ) = \frac{{T}_{ref} ( {R}_{sh , ref} ( {I}_{ph} ( T ) + {I}_{o} ( T ) ) - ( {V}_{oc , ref} + β ( T - {T}_{ref} ) ) )}{{n}_{ref} {V}_{t , ref} T} \qquad ( 14 )$$
$$D ( T ) = \frac{{R}_{sh , ref}}{{n}_{ref} {V}_{t , ref}} ( α + A ( T ) - \frac{{I}_{ph} ( T ) + {I}_{o} ( T )}{T} ) + \frac{A ( T )}{{I}_{o , ref} + A ( T )} - \frac{1}{T} \qquad ( 15 )$$
a step 3.2: solving the system of equations to get parameter values of the single diode model by using a trust region dogleg method.

5. The single diode model parameter calculation method for the photovoltaic module according to claim 4, further comprising:
a step 4: simulating performance indicators of the photovoltaic module via an expression of the single diode model obtained in the step 1.2 and the parameters of the single diode model obtained in the step 3.2, and calculating relative errors between simulated performance indicators and actual performance indicators of the photovoltaic module, thereby evaluating whether the calculation method is able to used for actual simulation.

6. A single diode model parameter calculation system for a photovoltaic module, the system comprising:
a data reading module, configured to acquire product information of the photovoltaic module;
a parameter calculation module, configured to calculate values of parameters of the single diode model; and
a simulation calculation module, configured to simulate performance indicators and relative errors of the photovoltaic module.

7. An electronic device, comprising: a processor, a memory and a computer program, wherein the memory is connected with the processor, the computer program is stored in the memory, when the electronic device is operating, the processor executes the computer program stored in the memory, so that the electronic device executes and implements a single diode model parameter calculation method for a photovoltaic module according to claim 1.
